(19) United States
(12) Patent Application Publication
(10) Pub. No.: US 2018/0044775 A1
(43) Pub. Date: Feb. 15, 2018

(54) HEAT REFLECTIVE COATING

(71) Applicant: General Cable Technologies Corporation, Highland Heights, KY (US)

(72) Inventors: Xi Zhang, Carmel, IN (US); Jon Michael Malinoski, Zionsville, IN (US); Vijay Mhetar, Carmel, IN (US)

(21) Appl. No.: 15/677,532

(22) Filed: Aug. 15, 2017

Related U.S. Application Data
(60) Provisional application No. 62/375,268, filed on Aug. 15, 2016.

(51) Int. Cl. C23C 14/20; C08L 91/06; C08F 14/18; C08F 10/06; C08F 14/06; C23C 14/08; C08F 10/02

(52) U.S. Cl. CPC C23C 14/20; C23C 14/085; C23C 14/083; C08L 91/06; C08F 10/02; C08F 10/06; C08F 14/06; C08F 14/18; H01B 7/42

(57) ABSTRACT

Cables including a heat-reflective layer are disclosed. The heat-reflective layer includes a polymeric layer and metal particles. The metal particles are on or near the exposed surface of the heat-reflective layer. Methods of making a heat-reflective layer and cables including a heat-reflective layer rare also disclosed.

### REFERENCE TO RELATED APPLICATIONS

The present application claims the priority benefit of U.S. provisional application Ser. No. 62/375,268, entitled HEAT REFLECTIVE COATING, filed Aug. 15, 2016, and hereby incorporates the same application herein by reference in its entirety.

### TECHNICAL FIELD

The present disclosure generally relates to cable coatings which exhibit increased heat reflectivity.

### BACKGROUND

Cables must reliably operate under a variety of conditions including operation in hot environments. For example, car cables are required to consistently operate in the heated engine compartment of an automobile for the vehicle to properly function. The current-carrying capacity of a cable is dependent on the operating temperature of the cable with operation above certain temperatures resulting in damage to the cable or to devices electrically coupled to the cable. It would be advantageous to provide a cable coating which can reflect external heat to allow cables to operate at lower temperatures when operating in a heated environment.

### SUMMARY

According to one embodiment, a cable comprises one or more conductors and a heat-reflective layer surrounding the one or more conductors. The heat-reflective layer includes a polymeric layer and metal particles. The metal particles are disposed on or near the exposed surface of the heat-reflective layer.

### BRIEF DESCRIPTION OF THE DRAWINGS

FIG. 1 depicts a schematic view of a multi-layer heat-reflective coating according to one embodiment.

### DETAILED DESCRIPTION

The operating temperature of a cable is determined by the cumulative effect of heating and cooling on the cable including heat generated through conductor resistance losses, heat absorbed from external sources, and heat emitted away from the cable through conduction, convection, and radiation. Cables operating in a hot environment, such as in a storage shed or near an automobile engine, absorb considerable heat form the environment reducing the current-carrying capacity and reliability of the cable. According to certain embodiments, a heat-reflective coating is described which can reduce the absorption of heat from external sources. The heat-reflective coating can be useful to reduce the operating temperature of cables operating in a hot environment. Generally, the heat-reflective coatings described herein can include a metallized polymeric layer which can reflect external heat away from the underlying cable.

For example, a heat-reflective coating in certain embodiments can be a metallized polymeric layer which includes metal particles to reflect external heat away from the heat-reflective coating. Suitable metal particles can include any particles which reflect infrared (“IR”) radiation including particles of, for example, aluminum, copper, gold, silver, tin, alloys thereof, and combinations thereof. In certain embodiments, the metal particles can also, or alternatively, include metal oxide particles such as, metal oxides of titanium, iron, cobalt, and mixtures thereof. As can be appreciated, the metal particles can reflect IR radiation away from the heat-reflecting coating to substantially lower heating of the underlying cable from external heat.

Metal particles can be deposited on a metallized polymeric layer through any suitable process. For example, it can be useful in certain embodiments to use a vacuum deposition or sputtering process to deposit the metal particles on an outer surface of a polymeric layer. Alternatively, the metal particles can be dispersed in an adhesive and applied to a polymeric film. Other variations are still possible. For example, in certain embodiments, the metal particles can be compounded and dispersed throughout a polymer dispersion before application to a cable using, for example, a melt extrusion process. In certain embodiments, a vacuum deposition or sputtering process can be preferred to maximize the reflection of external heat.

According to certain embodiments, the polymeric material for the polymeric film can be selected from any polymer demonstrating suitable properties such as high durability and high thermal stability. For example, suitable polymers can include polyvinyl chloride (“PVC”), polypropylene, polyolefins, polyethylene (including low-density polyethylene (“LDPE”), linear low-density polyethylene (“LLDPE”), medium-density polyethylene (“MDPE”), high-density polyethylene (“HDPE”) and cross-linked polyethylene (“XLPE”)), ethylene-vinyl acetate (“EVA”), polyurethanes, epoxies, tetra-fluoroethylene, hexafluoropropylene, fluoropolymer, acrylic, nylon, polyester, polyacrylics, silicones, polyamides, poly ether imides (“PEI”), polyimides, polyamide imides, PEI-siloxane copolymer, polymethylpentene (“PMP”), cyclic olefins, ethylene propylene diene monomer rubber (“EPDM”), ethylene propylene rubber (“EPR”), polyvinylidene difluoride (“PVDF”), PVDF copolymers, PVDF modified polymers, polytetrafluoroethylene (“PTFE”), polyvinyl fluoride (“PVF”), polychlorotrifluoroethylene (“PCTFE”), perfluoroalkoxy polymer (“PFA”), fluoroethylene-alkyl vinyl ether copolymer (“FEVE”), fluorinated ethylene propylene copolymer (“FEP”), ethylene tetrafluoroethylene copolymer (“ETFE”), ethylene chlorotrifluoroethylene resin (“ECTFE”), perfluorinated elastomer (“FFPM/FFKM”), fluorocarbon (“FPM/FKM”), polydimethylsiloxane (“PDMS”), polyphenylene ether (“PPE”), polyetheretherketone (“PEEK”), copolymers, blends, compounds, and combinations thereof.

As can be appreciated, the polymeric material can be selected based on the properties exhibited by the polymer. For example, it can be useful in certain embodiments to select a polymeric material which has high thermal conductivity such as polyolefins produced from alkenes having the general formula CₙH₂ₙ. In certain embodiments, a copolymer such as EVA can also be included in the polymeric film.

According to certain embodiments, the polymeric materials can also, or alternatively, include copolymers, and blends of several different polymers. For example, in certain embodiments, a suitable polyolefin can be formed from the polymerization of ethylene with at least one co-monomer selected from the group consisting of C₃ to C₂₀ alpha-olefins, C₃ to C₂₀ polyenes and combinations thereof. As will be appreciated, polymerization of ethylene with such co-monomers can produce ethylene/alpha-olefin copolymers or ethylene/alpha-olefin/diene terpolymers.

According to certain embodiments, the alpha-olefins can alternatively contain from 3 to 16 carbon atoms or can contain from 3 to 8 carbon atoms. A non-limiting list of suitable alpha-olefins includes propylene, 1-butene, 1-pentene, 1-hexene, 1-octene, and 1-dodecene.

Likewise, according to certain embodiments, a polyene can alternatively contain from 4 to 20 carbon atoms, or can contain from 4 to 15 carbon atoms. In certain embodiments, the polyene can be a diene further including, for example, straight chain dienes, branched chain dienes, cyclic hydrocarbon dienes, and non-conjugated dienes. Non-limiting examples of suitable dienes can include straight chain acyclic dienes: 1,3-butadiene; 1,4-hexadiene, and 1,6-octadiene; branched chain acyclic dienes: 5-methyl-1,4-hexadiene; 3,7-dimethyl-1,6-octadiene; 3,7-dimethyl-1,7-octadiene; and mixed isomers of dihydromyrcene and dihydroocimene; single ring alicyclic dienes: 1,3-cyclopentadiene; 1,4-cyclohexadiene; 1,5-cyclooctadiene; and 1,5-cyclododecadiene; multi-ring alicyclic fused and bridged ring dienes: tetrahydroindene; methyl tetrahydroindene; dicyclopentadiene; bicyclo-(2,2,1)-hepta-2-5-diene; alkenyl; alkylidene; cycloalkenyl; and cycloalkylidene norbornenes such as 5-methylene-2morbornene (MNB); 5-propenyl-2-norbornene; 5-isopropylidene-2-norbornene; 5-(4-cyclopentenyl)-2-norbornene; 5-cyclohexylidene-2-norbornene; and norbornene.

As can be appreciated, the components of the polymeric material can be polymerized by any suitable method including, for example, metallocene catalysis reactions. Details of metallocene catalyzation processes are disclosed in U.S. Pat. No. 6,451,894, U.S. Pat. No. 6,376,623, and U.S. Pat. No. 6,329,454, each of which is incorporated by reference herein. Metallocene-catalyzed olefin copolymers can also be commercially obtained through various suppliers including ExxonMobil Chemical Company™ (Houston, Tex.) and Dow Chemical Company™. Metallocene catalysis can allow for the polymerization of precise polymeric structures.

In certain embodiments, the polymer of a metallized polymeric layer can preferably be selected from one or more of polyvinyl chloride (“PVC”), polypropylene, polyolefins, polyethylene, ethylene-vinyl acetate (“EVA”), polyurethanes, epoxies, tetra-fluoroethylene, hexafluoropropylene, fluoropolymer, acrylic, nylon, and polyester.

As can be appreciated, suitable polymers can be modified in a variety of ways. For example, in certain embodiments, a polymer can be cross-linked to increase the durability of the polymeric material. As can be appreciated, a polymer can be cross-linked through chemical, irradiation, thermal, UV, and any other known cross-linking process. In certain embodiments, the polymeric material can be halogen free.

As can be appreciated, additional additives can be included in a metallized polymeric layer. For example one or more heat and UV stabilizers can be included to increase the durability and lifespan of a heat-reflective coating. Suitable heat and UV stabilizers are disclosed in U.S. Patent App. Pub. No. 2015/0376369 which is incorporated by reference herein.

Alternatively, or in addition, the metallized polymeric layer can be processed to improve the reflectivity of the layer. For example, an anti-scuffing coat or a shim roller can be used to increase, and maintain, the reflectivity of a metallized polymeric layer.

The heat-reflective coatings described herein can incorporate a variety of additional components to improve the properties of the heat-reflective coating. For example, certain heat-reflective coatings can include conductive particles and thermoregulatory materials. Inclusion of conductive particles can allow a heat-reflective coating to extract heat from the conductor while simultaneously preventing external heat from heating up the conductor from the surrounding environment. Thermoregulatory materials can delay the transmittance of heat from the surrounding environment to the conductor.

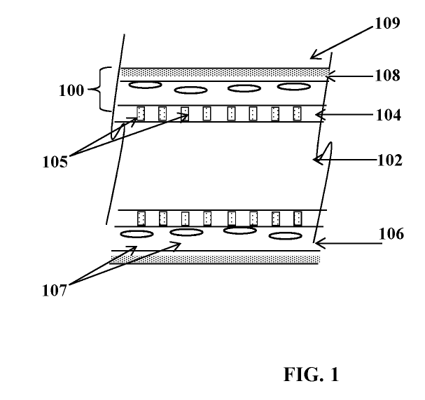

The conductive particles and the thermoregulatory materials can be incorporated into the metallized polymeric film directly or can alternatively be incorporated into one or more additional layers of a heat-reflective coating. For example, in certain embodiments, a heat-reflective coating 100 can be a multi-layer coating including three layers (104, 106, and 108) as depicted in FIG. 1 with each layer including a different component. The third, or outermost, layer 108 in such embodiments can be the metallized polymeric layer which includes metal particles 109 to reflect external heat.

In certain embodiments depicted by FIG. 1, a first, or inner, layer 104 of a heat-reflective coating 100 can be a polymeric layer which includes a plurality of dispersed conductive particles 105 to facilitate the transfer of heat away from the underlying cable or conductor 102. Suitable conductive particles 105 can include particles of any conductive metal such as, for example, particles of aluminum, copper, iron, silver, and combinations thereof. As can be appreciated however, other conductive materials such as particles of carbon black can also be suitable. In certain embodiments, the size of the conductive particles 105 can range from about 1 micron to about 50 microns. The first layer 104 can have a thickness of about 10 microns to about 50 microns in certain embodiments.

As further depicted by FIG. 1, a second layer 106 of a heat-reflective coating 100 can be a polymeric layer including a plurality of thermoregulatory reservoirs 107 which regulate heat flow through the coating layer 100. In certain embodiments, the thermoregulatory reservoirs 107 can regulate heat flow through inclusion of a phase change material. For example, in certain embodiments, the thermoregulatory reservoirs 107 can be discrete capsules which are at least partially filled with a suitable phase change material. Alternatively, suitable thermoregulatory reservoirs 107 can also be directly formed during an extrusion process through inclusion of a phase change material without the use of a capsule or the like. In certain embodiments, the second layer 106 can have a thickness of about 10 microns to about 100 microns.

Suitable phase change materials for the thermoregulatory reservoirs 107 can include any materials which are able to change phase through the absorption, or release, of heat. For example, suitable phase change materials can include waxes such as carnauba wax, paraffin wax, slack wax, scale wax, polyethylene wax, bayberry wax, palm wax, soybean wax, and combinations thereof. As can be appreciated, phase change materials can act as a buffer to delay flow of external heat through the heat-reflective coating 100 with the heat being stored by the phase change material. Such delays can be useful to prevent, for example, thermal shock caused by rapid heating and cooling of the conductor.

The polymeric material of the first, second and third layers 104, 106, and 108 can be the same or different in certain embodiments. For example, in certain embodiments, the polymer of the first layer 104 can be selected from polymers which exhibit high thermal conductivity and the polymer of the second layer 106 can be selected from polymers which exhibit high thermal conductivity and tolerate high filler loadings. Generally, suitable polymers for each of the first, second, and third layers 104, 106, and 108 can be selected from any of the polymers suitable for the metallized polymeric film.

As can be appreciated, the three layers (104, 106, and 108) can be bonded to each other to form a single heat-reflective coating 100. For example, in certain embodiments, each of the three layers can be adhered to adjacent layers with an adhesive and the use of a hot calendaring roller or the like. As can be appreciated, other processes known in the art can also be suitable to bond the layers 104, 106, and 108 together. For example, each of the three layers can be co-extruded in certain embodiments. Co-extrusion can eliminate the need for an adhesive. Alternatively, each layer can be extruded in subsequent steps. In certain embodiments, adhesive can also be applied to the first layer 104 to allow the heat-reflective coating 100 to be adhered to the underlying cable 102.

In embodiments employing an adhesive, suitable adhesives can generally include pressure-sensitive adhesives and contact adhesives as known in the art. In certain embodiments, specific examples of suitable adhesives can include polycyanoacrylate adhesives, polyurethane adhesives, epoxy adhesives, acrylic adhesives, polyvinyl acetate adhesives, and multi-part adhesives such as polyester resin and polyurethane resins, polyol and polyurethane resins, acrylic polymer and polyurethane resins, and combinations thereof.

In certain embodiments, a heat-reflective coating can be supplied as a strip. As can be appreciated, strips can be formed in a variety of ways. For example, strips can be formed by extruding the heat-reflective coating 100 of FIG. 1 into a continuous cylindrical sleeve and then helically cutting the continuous cylindrical sleeve to form a strip. Once formed as a strip, the heat-reflective coating can be wound on a reel until applied to a cable.

In embodiments wherein the heat-reflective coating is supplied as a strip or the like, the heat-reflective coating can be applied around a cable in any suitable manner. For example, in certain embodiments, a coating layer can be helically or longitudinally wound around a cable under tension to reduce the absorption of external heat. As can be appreciated however, many variations are possible. For example, a coating layer can alternatively only be applied to select portions of a cable which experience direct sunlight. In embodiments wrapping a cable, the edges of the heat-reflective coating can overlap to form a continuous sleeve around the cable.

As can be appreciated, many design variations are possible for the heat-reflective coatings described herein. For example, in certain embodiments, one or more components such as the conductive particles can be incorporated into an underlying cable jacket or sheath. For example, the inclusion of conductive particles into a cable jacket can increase the emissivity of the cable and cable jacket and can allow the cable to operate at a lower temperature without requiring a heat-reflective coating to incorporate the conductive particles. In such embodiments, the heat-reflective coating can include only a metallized polymeric layer or include only a metallized polymer layer and a thermoregulatory layer.

In certain embodiments, multiple components of a heat-reflective coating such as the conductive particles and the thermoregulatory reservoirs can be included in a single layer such as the metallized polymeric layer. For example, in certain embodiments, a metallized polymeric layer can further include a thermoregulatory material through inclusion of a phase change material.

In certain embodiments, certain aspects of the heat-reflective coating can be applied directly applied to a cable using a suitable coating process such as a melt extrusion process. For example, in certain embodiments, a heat emissivity coating layer can be formed by extruding a polymer including conductive particles around a cable. As can be appreciated, similar processes can be used to form other layers such as a thermoregulatory layer.

In certain embodiments, a metallized polymeric layer can similarly be applied by dispersing metal particles into a polymer before application to the cable using a suitable coating process. Such embodiments are well suited for incorporation of heat-reflective coatings into existing manufacturing processes. As can be appreciated however, such metallized polymeric coatings can be less efficient at reflecting external heat due to dispersion of metal powders below the exterior surface of the heat-reflective coating.

As can be appreciated, a variety of coating methods can be used to apply coating layers. For example, a spraying process, a powder coating process, a dipping process, a film coating process, or a melt extrusion process can each be used to apply polymers to a cable as known in the art.

A powder coating process to apply a polymeric coating can generally include the steps of spraying a powdered polymer onto the cable, and heating the sprayed cable to melt or soften the powdered polymer around the cable to form a layer. As can be appreciated, the powder process can be solvent free and can be continuously operated by use of a spray gun or electro spray gun to continuously apply powder. In certain embodiments, a powder coating process can optionally be cured in-line with the powder coating process or through a post-coating process using, for example, a chemical curing process, a thermal curing process, a mechanical curing process, an irradiation curing process, a UV curing process, or an e-beam curing process.

Film coating processes can generally include the steps of wrapping the exterior surface of a cable with a polymeric film and heat the wrapped cable to a melting point temperature of the polymer to soften the polymer and form a layer.

In certain alternative embodiments, a vacuum deposition or sputtering process can be used to apply metal particles to an insulation or jacket layer of a cable.

In other alternative embodiments, a heat-reflective coating layer can be a metal foil. For example, an aluminum foil can be wrapped around a cable for improved reflectivity in certain embodiments.

### EXAMPLES

### Example 1

A cable was covered with aluminum foil and placed in a 200° C. heated oven. The temperature of the oven during the experiment was decreased from 152° C. to 87° C. over a 12 minute period. The temperature of the cable was compared to a similar cable without the aluminum foil using a temperature probe. The temperature of the cable with aluminum foil was found to be 8.9° C. less than the power cable without the aluminum foil cover. During the experiment, the temperature of the power cable with the aluminum foil increased from 33.4° C. to 40.2° C., whereas the temperature of the power cable without the aluminum foil increased from 33.5° C. to 49.1° C.

### Example 2

Similar to example 1, example 2 was conducted using an oven held at 230° C. The temperature of the oven during the experiment was decreased from 185° C. to 97° C. over an 11 minute period. The temperature of the cable with aluminum foil was found to be 10.5° C. less than the cable without the aluminum foil cover. During the experiment, the temperature of the cable with the aluminum foil increased from 34.2° C. to 43.5° C., while the temperature of the cable without the aluminum foil cover increased from 34.7° C. to 54.1° C.

As evidenced by the examples, the use of a heat-reflective coating improves the thermal operating temperature of a cable in a hot environment as compared to a similar cable without a heat-reflective coating.

The dimensions and values disclosed herein are not to be understood as being strictly limited to the exact numerical values recited. Instead, unless otherwise specified, each such dimension is intended to mean both the recited value and a functionally equivalent range surrounding that value.

It should be understood that every maximum numerical limitation given throughout this specification includes every lower numerical limitation, as if such lower numerical limitations were expressly written herein. Every minimum numerical limitation given throughout this specification will include every higher numerical limitation, as if such higher numerical limitations were expressly written herein. Every numerical range given throughout this specification will include every narrower numerical range that falls within such broader numerical range, as if such narrower numerical ranges were all expressly written herein.

Every document cited herein, including any cross-referenced or related patent or application, is hereby incorporated herein by reference in its entirety unless expressly excluded or otherwise limited. The citation of any document is not an admission that it is prior art with respect to any invention disclosed or claimed herein or that it alone, or in any combination with any other reference or references, teaches, suggests, or discloses any such invention. Further, to the extent that any meaning or definition of a term in this document conflicts with any meaning or definition of the same term in a document incorporated by reference, the meaning or definition assigned to that term in the document shall govern.

The foregoing description of embodiments and examples has been presented for purposes of description. It is not intended to be exhaustive or limiting to the forms described. Numerous modifications are possible in light of the above teachings. Some of those modifications have been discussed and others will be understood by those skilled in the art. The embodiments were chosen and described for illustration of various embodiments. The scope is, of course, not limited to the examples or embodiments set forth herein, but can be employed in any number of applications and equivalent articles by those of ordinary skill in the art. Rather it is hereby intended the scope be defined by the claims appended hereto.

What is claimed is:

1. A cable comprising:
one or more conductors; and
a heat-reflective layer surrounding the one or more conductors, the heat-reflective layer comprising a polymeric layer and metal particles; and
wherein the metal particles are disposed on or near the exposed surface of the heat-reflective layer.

2. The cable of claim 1, wherein the metal particles comprise one or more of aluminum, copper, gold, silver, tin, and alloys thereof.

3. The cable of claim 1, wherein the metal particles comprise one or more metal oxides of titanium, iron, and cobalt.

4. The cable of claim 1, wherein the metal particles are deposited on the polymeric layer by vacuum deposition or sputtering.

5. The cable of claim 1, wherein the metal particles are dispersed through the polymeric layer.

6. The cable of claim 1, wherein the polymeric layer comprises one or more of polyvinyl chloride (“PVC”), polypropylene, polyolefins, polyethylene, ethylene-vinyl acetate (“EVA”), polyurethanes, epoxies, tetra-fluoroethylene, hexafluoropropylene, fluoropolymer, acrylic, nylon, and polyester.

7. The cable of claim 1, wherein the heat-reflective layer further comprises an anti-scuffing coating.

8. The cable of claim 1, wherein the heat-reflective layer is processed with a shim roller.

9. The cable of claim 1, wherein the heat-reflective layer further comprises conductive particles, and wherein the conductive particles are within the heat-reflective layer.

10. The cable of claim 9, wherein the conductive particles comprise one or more of aluminum, copper, iron, silver, and carbon black.

11. The cable of claim 1, wherein the heat-reflective layer further comprises thermoregulatory reservoirs.

12. The cable of claim 11, wherein the thermoregulatory reservoirs comprise a phase change material comprising one or more of carnauba wax, paraffin wax, slack wax, scale wax, polyethylene wax, bayberry wax, palm wax, and soybean wax.

13. The cable of claim 1, wherein the heat-reflective layer further comprises conductive particles and thermoregulatory reservoirs, and wherein the conductive particles are within the heat-reflective layer.

14. The cable of claim 13, wherein the heat-reflective layer comprises a plurality of layers and wherein at least one of the metal particles, the conductive particles, and the thermoregulatory reservoirs are in different layers.

15. The cable of claim 14, wherein the plurality of layers are bonded together with a pressure-sensitive adhesive.

16. The cable of claim 1, wherein the heat-reflective layer comprises a strip.

17. The cable of claim 16, wherein the strip is helically wound or longitudinally wound around the cable.

18. The cable of claim 1, wherein the heat-reflective layer is a cable jacket layer.

19. The cable of claim 1, wherein the polymeric layer is crosslinked.

20. The cable of claim 1 is a power cable.
